(19) United States
(12) Patent Application Publication
(10) Pub. No.: US 2011/0127158 A1
(43) Pub. Date: Jun. 2, 2011

(54) MANUFACTURING METHOD OF SEMICONDUCTOR INTEGRATED CIRCUIT DEVICE

(75) Inventors: Takashi HAMAYA, Kanagawa (JP); Hidenori SUZUKI, Kanagawa (JP); Yuichi HARANO, Kanagawa (JP); Masahiko ITO, Kanagawa (JP)

(73) Assignee: RENESAS ELECTRONICS CORPORATION, Kanagawa (JP)

(21) Appl. No.: 12/940,159

(22) Filed: Nov. 5, 2010

(30) Foreign Application Priority Data
Dec. 1, 2009 (JP) 2009-273240

(51) Int. Cl. C23C 14/34

(52) U.S. Cl. 204/192.25

(57) ABSTRACT

In a copper damascene wiring process, a tantalum-based laminated film, which is used as a barrier metal film, is continuously formed in a sputtering deposition chamber. When the continuous deposition process is discontinuously applied to a number of wafers, a tantalum film and a tantalum nitride film which are relatively thin are alternately deposited over an inner surface of a shield in a sputter deposition chamber, which results in a thickness of the deposited film being on the order of several thousand nanometers. The deposited film peels off due to internal stress therein to generate foreign material or particles. To counteract this, a tantalum film, which is much thicker than the tantalum film formed over the wafer at one time, is formed over the substantially inner wall of the chamber at predetermined intervals when repeatedly depositing the tantalum nitride film and the tantalum film in the sputtering deposition chamber.

### CROSS-REFERENCE TO RELATED APPLICATIONS

The disclosure of Japanese Patent Application No. 2009-273240 filed on Dec. 1, 2009 including the specification, drawings and abstract is incorporated herein by reference in its entirety.

### BACKGROUND OF THE INVENTION

The present invention relates to a technique effectively applied to metal sputtering deposition technology in a manufacturing method of a semiconductor integrated circuit device (or semiconductor device).

Japanese Unexamined Patent Publication Number No. Hei 11(1999)-269644 (Patent Document 1) discloses a technique of sputter etching for removing a natural oxide film or the like in a different chamber before deposition of a metal film or the like by sputtering. In the technique, a film or the like of metal with a small stress, such as aluminum, is previously formed over an inner wall of the different chamber to suppress falling of particles of silicon oxide-based material.

Japanese Unexamined Patent Publication Number No. 2000-331989 (Patent Document 2) discloses a technique in which an inner wall of a chamber in a dry etching device for a silicon oxide film is uniformly covered with a silicon oxide film to thereby suppress falling of silicon oxide-based particles unevenly deposited.

Japanese Unexamined Patent Publication Number No. Hei 4(1992)-286112 (Patent Document 3) discloses a technique in which a TiN film having a stress opposite to that of a TiN film previously deposited over a wafer is deposited at an inner surface of a shield of a chamber in a sputter deposition device for TiN to thereby suppress falling of particles or the like.

Japanese Unexamined Patent Publication Number No. 2007-311461 (Patent Document 4) discloses a technique for continuously depositing a Ti film and a TiN film by sputtering in the same chamber. In the technique, before depositing the above Ti film, another Ti film is deposited over a shutter by sputtering so as to reduce influences on the Ti film due to the residual nitrogen.

### Related Art Documents

### [Patent Documents]

### [Patent Document 1]

Japanese Unexamined Patent Publication Number No. Hei 11(1999)-269644

### [Patent Document 2]

Japanese Unexamined Patent Publication Number No. Hei 2000-331989

### [Patent Document 3]

Japanese Unexamined Patent Publication Number No. Hei 4(1992)-286112

### [Patent Document 4]

Japanese Unexamined Patent Publication Number No. Hei 2007-311461

### SUMMARY OF THE INVENTION

In a copper damascene wiring process, for example, a tantalum-based laminated film comprised of a tantalum nitride film as a lower layer and a tantalum film as an upper layer is used as a barrier metal film. Formation of the tantalum-based laminated film is continuously performed in the same sputtering deposition chamber in a normal mass production process.

The inventors of the present invention have studied about such a continuous deposition process, and found out the following problems. That is, when the continuous deposition process is discontinuously repeated on a number of wafers, the tantalum film and the tantalum nitride film which are relatively thin are alternately deposited over an inner surface of a shield in a sputtering deposition chamber (substantially inner surface of the chamber), which results in thickness of a deposited film on the order of one thousand nanometers to several thousand nanometers at the time of the wafer process. Thus, when the thickness of the deposited film in the wet process (total thickness of the deposited film in the wet process) is large, the deposited film may be peeled off due to an internal stress therein, which causes foreign material or particles. The foreign material or particles may cause failures of the wiring. The tantalum film and the tantalum nitride film both have the same direction of stress (compression stress), and thus may be peeled off due to the increased internal stress of the laminated film.

The invention of the present application is to solve the above problems.

Accordingly, it is an object of the invention to provide a manufacturing process of a semiconductor integrated circuit device with high reliability.

The above, other objects, and novel features of the invention will become apparent from the description of the present specification with reference to the accompanying drawings.

The outline of representative aspects of the invention disclosed in the present application will be briefly described below.

That is, the invention of the present application is directed to a manufacturing method of a semiconductor integrated circuit device which includes the step of depositing a tantalum film for preventing foreign material at predetermined intervals in repeatedly depositing a tantalum nitride film and a tantalum film over a number of wafers in a sputtering deposition chamber. The tantalum film for preventing foreign material is much thicker than the tantalum film formed over the wafer at one time.

The effects obtained by the representative aspects of the invention disclosed in the present application will be briefly described below.

That is, in a case where the tantalum nitride film and the tantalum film are repeatedly deposited over each of a number of wafers in the sputtering deposition chamber, the manufacturing method of the semiconductor integrated circuit device includes the step of depositing over the substantial inner wall of the chamber the tantalum film for preventing foreign material at the predetermined intervals. The tantalum film for preventing foreign material has a thickness much larger than that of the tantalum film formed over the wafer at one time. As a result, the surface of the deposited film at the time of the wafer process is coated with the thick film having a relatively small Young's modulus, which can reduce foreign material and particles.

### BRIEF DESCRIPTION OF THE DRAWINGS

FIG. 1 is a cross-sectional view of the structure of a semiconductor integrated circuit device of interest at the time of completion of a pad opening at an aluminum pad in a manufacturing method of the semiconductor integrated circuit device according to one embodiment of the present application;

FIG. 2 is a cross-sectional flow diagram of the semiconductor integrated circuit device in a wiring embedding process of the manufacturing method thereof according to the embodiment of the present application (at the time of completion of formation of a trench and a via);

FIG. 3 is a cross-sectional flow diagram of the semiconductor integrated circuit device in the wiring embedding process of the manufacturing method thereof according to the embodiment of the present application (at the time of completion of formation of a Ta film);

FIG. 4 is a cross-sectional view of the semiconductor integrated circuit device in the wiring embedding process of the manufacturing method thereof according to the embodiment of the present application (at the time of completion of formation of a copper seed film);

FIG. 5 is a cross-sectional view of the semiconductor integrated circuit device in the wiring embedding process of the manufacturing method thereof according to the embodiment of the present application (at the time of completion of copper plating);

FIG. 6 is a cross-sectional view of the semiconductor integrated circuit device in the wiring embedding process of the manufacturing method thereof according to the embodiment of the present application (at the time of completion of metal CMP);

FIG. 7 is an exemplary diagram of an upper surface of a multi-chamber type manufacturing device used in the wiring embedding process of the manufacturing method of the semiconductor integrated circuit device according to the embodiment of the present application;

FIG. 8 is an exemplary cross-sectional view of a sputtering chamber for tantalum and tantalum nitride in the multi-chamber type manufacturing device shown in FIG. 7 (at the time of deposition over the wafer or the like);

FIG. 9 is an exemplary cross-sectional view of the sputtering chamber for tantalum and tantalum nitride in the multi-chamber type manufacturing device shown in FIG. 7 (at the time of introduction or discharge into or from the wafer or the like);

FIG. 10 is a partial enlarged cross-sectional view of a shield enlargement region R1 shown in FIG. 8;

FIG. 11 is a process block flow diagram for explaining a procedure in applying the wiring embedding process to mass production in the manufacturing method of the semiconductor integrated circuit device according to the embodiment of the present application;

FIG. 12 is a data plot diagram of the plot of the average number of foreign particles (per wafer) contained in a finished product after completion of deposition of tantalum and tantalum nitride films by sputtering with respect to the thickness of a tantalum film which is a thick metal film (inner wall coating film);

FIG. 13 is a data plot diagram of the plot of the average number of foreign particles (per wafer) contained in a finished product after completion of deposition of tantalum and tantalum nitride films by sputtering with respect to the total thickness of the deposited film directly before a deposition process of the thick metal film (inner wall coating film) (at the time between the inner wall coating film deposition process and a previous inner wall coating film deposition process);

FIG. 14 is a cross-sectional flow diagram of a semiconductor integrated circuit device in a wiring embedding process of the manufacturing method thereof according to another embodiment of the present application (at the time of completion of formation of a trench and a via);

FIG. 15 is a cross-sectional flow diagram of the semiconductor integrated circuit device in the wiring embedding process of the manufacturing method thereof according to another embodiment of the present application (at the time of completion of formation of a Ta film);

FIG. 16 is a cross-sectional flow diagram of the semiconductor integrated circuit device in the wiring embedding process of the manufacturing method thereof according to another embodiment of the present application(at the time of completion of etching the bottom of a hole);

FIG. 17 is a cross-sectional flow diagram of the semiconductor integrated circuit device in the wiring embedding process of the manufacturing method thereof according to another embodiment of the present application (at the time of completion of formation of an additional Ta film);

FIG. 18 is a cross-sectional flow diagram of the semiconductor integrated circuit device in the wiring embedding process of the manufacturing method thereof according to another embodiment of the present application (at the time of completion of forming a copper seed film);

FIG. 19 is a cross-sectional flow diagram of the semiconductor integrated circuit device in the wiring embedding process of the manufacturing method thereof according to another embodiment of the present application (at the time of completion of copper plating); and

FIG. 20 is a cross-sectional flow diagram of the semiconductor integrated circuit device in the wiring embedding process of the manufacturing method thereof according to another embodiment of the present application (at the time of completion of metal CMP).

### DETAILED DESCRIPTION OF THE PREFERRED EMBODIMENTS

### Outline of Preferred Embodiments

First, the outline of representative preferred embodiments of the invention disclosed in the present application will be described below.

1. A manufacturing method of a semiconductor integrated circuit device includes the following steps of: (a) introducing a wafer to be processed, into a chamber; (b) depositing a tantalum nitride film having a first thickness over the wafer to be processed in the chamber by sputtering; (c) after the step (b), depositing a first tantalum film having a second thickness over the wafer to be processed in the chamber by the sputtering; (d) discharging the wafer to be processed to an outside of the chamber; (e) sequentially applying a lower-level process cycle including the steps (a) to (d) to a plurality of wafers to be processed that are different from the wafer belonging to a previous lower-level process cycle; (f) after the step (e), depositing a second tantalum film having a third thickness much larger than the second thickness, over an inner wall of the chamber by sputtering in the chamber; and (g) repeating a higher-level process cycle including the steps (a) to (f).

2. In the manufacturing method of the semiconductor integrated circuit device according to Item 1, the step (f) is performed before the total thickness of the deposited film in the last wafer process exceeds 1000 nm.

3. In the manufacturing method of the semiconductor integrated circuit device according to Item 1 or 2, the step (f) is performed after the total thickness of the deposited film in the last wafer process exceeds 300 nm.

4. In the manufacturing method of the semiconductor integrated circuit device according to any one of Items 1 to 3, the third thickness is not less than 100 nm, and less than 500 nm.

5. In the manufacturing method of the semiconductor integrated circuit device according to any one of Items 1 to 4, the sum of the first thickness and the second thickness is not less than 5 nm, and less than 30 nm.

6. In the manufacturing method of the semiconductor integrated circuit device according to any one of Items 1 to 5, the step (f) is performed after the total thickness of the deposited film in the last wafer process exceeds 500 nm.

7. In the manufacturing method of the semiconductor integrated circuit device according to any one of Items 1 to 6, the third thickness is not less than 150 nm, and less than 350 nm.

8. In the manufacturing method of the semiconductor integrated circuit device according to any one of Items 1 to 7, the step (f) is performed before the total thickness of the deposited film in the last wafer process exceeds 800 nm.

9. A manufacturing method of a semiconductor integrated circuit device includes the following steps of: (a) introducing a wafer to be processed, into a first chamber; (b) depositing a tantalum nitride film having a first thickness over the wafer to be processed in the first chamber; (c) after the step (b), taking the wafer to be processed out of the first chamber to introduce the wafer into a second chamber; (d) depositing a ruthenium film having a second thickness over the wafer to be processed, in the second chamber by sputtering; (e) discharging the wafer to be processed to an outside of the second chamber; (f) sequentially applying a lower-level process cycle including the steps (a) to (e) to a plurality of wafers to be processed that are different from the wafer belonging to a previous lower-level process cycle; (g) after the step (f), depositing a tantalum film over an inner wall of the first chamber by sputtering in the first chamber, the tantalum film having a third thickness much larger than the first thickness; and (h) repeating a higher-level process cycle including the steps (a) to (g).

10. In the manufacturing method of the semiconductor integrated circuit device according to Item 9, the step (g) is performed before a total thickness of the deposited film in the last wafer process exceeds 1000 nm.

11. In the manufacturing method of the semiconductor integrated circuit device according to Item 9 or 10, the step (g) is performed after the total thickness of the deposited film in the last wafer process exceeds 300 nm.

12. In the manufacturing method of the semiconductor integrated circuit device according to any one of Items 9 to 11, the third thickness is not less than 100 nm and less than 500 nm.

13. In the manufacturing method of the semiconductor integrated circuit device according to any one of Items 9 to 12, the second thickness is not less than 5 nm and less than 20 nm.

14. In the manufacturing method of the semiconductor integrated circuit device according to any one of Items 9 to 13, the step (g) is performed after the total thickness of the deposited film in the last wafer process exceeds 500 nm.

15. In the manufacturing method of the semiconductor integrated circuit device according to any one of Items 9 to 14, the third thickness is not less than 150 nm and less than 350 nm.

16. In the manufacturing method of the semiconductor integrated circuit device according to any one of Items 9 to 15, the step (g) is performed before the total thickness of the deposited film in the last wafer process exceeds 800 nm.

17. A manufacturing method of a semiconductor integrated circuit device includes the following steps of: (a) introducing a wafer to be processed, into a chamber; (b) depositing a first barrier metal film having a first thickness over the wafer to be processed in the chamber by sputtering, the first barrier metal film containing a first metal nitride as a principal component; (c) after the step (b), depositing a second barrier metal film having a second thickness over the wafer to be processed in the chamber by sputtering, the second barrier metal film containing the first metal as a principal component; (d) discharging the wafer to be processed to an outside of the chamber; (e) sequentially applying a lower-level process cycle including the steps (a) to (d) to a plurality of wafers to be processed that are different from the wafer belonging to a previous lower-level process cycle; (f) after the step (e), depositing an inner wall coating film over an inner wall of the chamber by sputtering in the chamber, the inner wall coating film having a third thickness much larger than the second thickness, and containing a first metal as a principal component; and (g) repeating a higher-level process cycle including the steps (a) to (f). Each of the first barrier metal film and the inner wall coating film has a compression stress.

18. In the manufacturing method of the semiconductor integrated circuit device according to Item 17, the step (f) is performed before the total thickness of the deposited film in the last wafer process exceeds 1000 nm.

19. In the manufacturing method of the semiconductor integrated circuit device according to Item 17 or 18, the step (f) is performed after the total thickness of the deposited film in the last wafer process exceeds 300 nm.

20. In the manufacturing method of the semiconductor integrated circuit device according to any one of Items 17 to 19, the third thickness is not less than 100 nm and less than 500 nm.

21. In the manufacturing method of the semiconductor integrated circuit device according to any one of Items 17 to 20, the sum of the first thickness and the second thickness is not less than 5 nm and less than 30 nm.

22. In the manufacturing method of the semiconductor integrated circuit device according to any one of Items 17 to 21, the step (f) is performed after the total thickness of the deposited film in the last wafer process exceeds 500 nm.

23. In the manufacturing method of the semiconductor integrated circuit device according to any one of Items 17 to 22, the third thickness is not less than 150 nm and less than 350 nm.

24. In the manufacturing method of the semiconductor integrated circuit device according to any one of Items 17 to 23, the step (f) is performed before the total thickness of the deposited film in the last wafer process exceeds 800 nm.

25. In the manufacturing method of the semiconductor integrated circuit device according to any one of Items 1 to 8, a Young's modulus of the second tantalum film is lower than that of the tantalum nitride film.

26. In the manufacturing method of the semiconductor integrated circuit device according to any one of Items 9 to 16, a Young's modulus of the tantalum film is lower than that of the tantalum nitride film.

27. In the manufacturing method of the semiconductor integrated circuit device according to any one of Items 17 to 24, a Young's modulus of the inner wall coating film is lower than that of the first barrier metal film.

28. In the manufacturing method of the semiconductor integrated circuit device according to Item 17, the second barrier metal film has a compression stress, like the first barrier metal film and the inner wall coating film.

29. A manufacturing method of a semiconductor integrated circuit device includes the following steps of: (a) introducing a wafer to be processed into a chamber; (b) depositing a first barrier metal film having a first thickness over the wafer to be processed by sputtering in the chamber; (c) after the step (b), depositing a second barrier metal film having a second thickness over the wafer to be processed by sputtering in the chamber; (d) discharging the wafer to be processed to an outside of the chamber; (e) sequentially applying a lower-level process cycle including the steps (a) to (d) to a plurality of wafers to be processed that are different from the wafer belonging to a previous lower-level process cycle; (f) after the step (e), depositing an inner wall coating film over an inner wall of the chamber by sputtering in the chamber, the inner wall coating film having a third thickness larger than the total thickness of the first film and the second film; and (g) repeating a higher-level process cycle including the steps (a) to (f). Each of the first barrier metal film and the second barrier metal film has a compression stress, and the inner wall coating film is the same as one of the first barrier metal film and the second barrier metal film.

30. In the manufacturing method of the semiconductor integrated circuit device according to Item 29, the inner wall coating film is the same as one having a lower Young's modulus of the first barrier metal film and the second barrier metal film.

### Explanation of Description Format, Basic Terms, and Usage in Present Application

1. The description of the following preferred embodiments in the present application may be divided into sections, or based on the respective embodiments, for convenience if necessary, but these embodiments are not independent from each other except when specified otherwise. One of the embodiments corresponds to each part of a single example, or is a part of the details of the other, a modified example of a part or all of the other, or the like. The repeated description of the same part will be omitted in principal. Each component of the embodiments is not essential unless otherwise specified, except when the number of the components is limited in principle, or unless the context clearly indicates otherwise.

Further, the term “semiconductor device” or “semiconductor integrated circuit device” as used in the present application mainly means a single device of various kinds of transistors (active elements), or a device including these various transistors, such as a resistor or a capacitor, integrated on a semiconductor chip or the like (for example, a monocrystalline silicon substrate). Various types of representative transistors can include, for example, a metal insulator semiconductor field effect transistor (MISFET), typified by a metal oxide semiconductor field effect transistor (MOSFET). At this time, the typical integrated circuit structure can include, for example, a complementary metal insulator semiconductor (CMIS) type integrated circuit, typified by a complementary metal oxide semiconductor (CMOS) type integrated circuit with a combination of an N-channel type MISFET and a P-channel type MISFET. The above-mentioned term “Metal” is not limited to single metal, but also contains a conductive material (for example, polysilicon and the like).

Normally, the wafer process of present semiconductor integrated circuit devices, that is, a large scale integration (LSI) can be broadly classified into a front end of line (FEOL) process and a back end of line (BEOL) process. The FEOL process includes a step from delivery of a silicon wafer as a raw material to a premetal process (involving formation of an interlayer insulating film between a low end of a M1 wiring layer and a gate electrode structure, formation of a contact hole, formation of a tungsten plug, embedding, and the like). The BEOL process includes a step from the formation of the Ml wiring layer to the formation of a pad opening in a final passivation film on an aluminum pad electrode (including a wafer level package process). Among the FEOL process, a gate electrode patterning step, a contact hole formation step, and the like are microfabrication steps, specifically, requiring a fine process. On the other hand, in the BEOL process, a via and trench formation step requires a fine process in a local wiring as a relatively lower layer (for example, fine embedded wirings M1 to M3 in an embedded wiring structure having four layers, or fine embedded wirings M1 to M5 in an embedded wiring structure having about ten layers). The term “MN (normally, N=about anyone of 1 to 15” means an N-th layered wiring from the bottom. The M1 indicates the first layer wiring, and the M3 indicates the third layer wiring.

2. Likewise, in the description of the embodiments or the like, the phrase “X made of A” about material, component, or the like does not exclude a member containing an element other than A as a principal component unless otherwise specified, or unless the context clearly indicates otherwise. For example, as to a component, the above phrase means “X containing A as a principal component” or the like.

It is apparent that for example, the term “a silicon member” or the like is not limited to pure silicon, and may include multicomponent alloy containing SiGe alloy or other silicon materials as a principal component, and a member containing other additives or the like. The same goes for a “copper wiring” (also including a copper-based wiring or the like), a “tantalum film”, a “tantalum nitride film”, or a “ruthenium film”, or the like.

Likewise, it is apparent that the term “silicon oxide film” or “silicon oxide-based insulating film” or the like includes not only a relatively pure undoped silicon dioxide, but also a thermally-oxidized film made of, for example, fluorosilicate glass (FSG), TEOS-based silicon oxide, silicon oxicarbide (SiOC), carbon-doped silicon oxide, organosilicate glass (OSG), phosphorus silicate glass (PSG), borophosphosilicate glass (BPSG), or the like, a CVD oxide film, a coating-type silicon oxide film, such as spin on glass (SOG), or a nano-clustering silica (NCS), a silica-based Low-k insulating film (porous insulating film), a composite film with another silicon insulating film containing the above component as a principal component.

Silicon insulating films generally used in the field of semiconductor devices are a silicon nitride-based insulating film, in addition to the silicon oxide-based insulating film. Suitable materials of such a kind include SiN, SiCN, SiNH, SiCNH, and the like. The term “silicon nitride” as used herein include both SiN and SiNH, unless specified otherwise. Likewise, the term “SiCN” as used herein includes both SiCN and SiCNH, unless specified otherwise.

SiC has the similar properties to those of SiN, and SiON should be often classified into a silicon oxide-based insulating film.

3. Likewise, it is apparent that preferred examples of graphics, positions, properties, and the like will be described below in the embodiments, but the invention is not strictly limited thereto unless otherwise specified, or unless the context clearly indicates otherwise.

4. Further, when referring to a specific value or quantity, the invention may have a value exceeding the specific value, or may have a value less than the specific value, unless otherwise specified, except when limited to the specific value in theory, or unless the context clearly indicates otherwise.

5. The term “wafer” generally indicates a monocrystalline silicon wafer over which a semiconductor integrated circuit device (note that the same goes for a semiconductor device, and an electronic device) is formed, but may include a composite wafer of an insulating substrate, such as an epitaxial wafer, an SOI wafer, or a LCD glass substrate, and a semiconductor layer, or the like.

### DETAILS OF PREFERRED EMBODIMENTS

The preferred embodiments will be further described below in detail. In each drawing, the same or similar part is designated by the same or similar reference character or numeral, and a description thereof will not be repeated in principal.

In the accompanying drawings, hatching or the like may be omitted even in the cross-sectional view when the drawing possibly becomes complicated or when apart shown in the drawing is apparently distinguished from a cavity. In a related matter, when the presence of a hole closed in a planar manner is clearly understood from the description thereof, a background outline of the hole may be often omitted. Further, hatching may be provided even in any drawing other than the cross-sectional view in order to clearly show that a part of interest in the drawing is not the cavity.

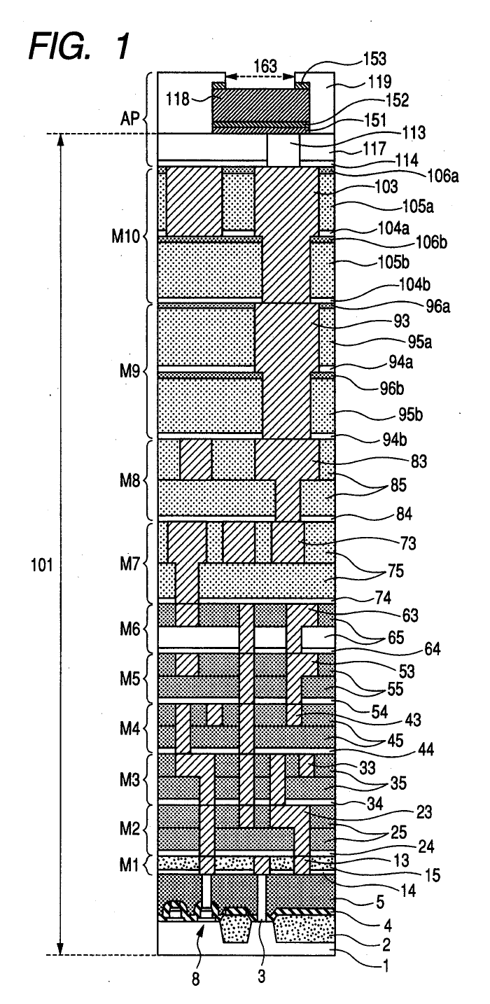

1. Explanation of Device Cross-Sectional Structure at Time of Completion of Pad Opening at Aluminum-based Pad of Semiconductor Integrated Circuit Device of Interest in Manufacturing Method Thereof According to First Embodiment of Present Application (mainly see FIG. 1)

FIG. 1 is a device cross-sectional view (at the time of completion of the pad opening) showing one example of a cross-sectional structure of a semiconductor integrated circuit device of a 65 nm technology node provided by the manufacturing method of the semiconductor integrated circuit device according to the first embodiment of the invention of the present application. The outline of the structure of the semiconductor integrated circuit device according to the embodiment of the present application will be described below based on FIG. 1.

As shown in FIG. 1, for example, a gate electrode 8 of a P-channel MOSFET or N-channel MOSFET is formed over the device surface of a P-type monocrystalline silicon substrate 1 separated by a shallow trench isolation (STI) type element isolation field insulating film 2. Over them, a silicon nitride liner film 4 (for example, of about 30 nm), which is an etching stop film, is formed. A premetal interlayer insulating film 5 is formed over the liner film 4. The insulating film 5 is much thicker than the liner film 4. The insulating film 5 is comprised of an ozone TEOS silicon oxide film (for example, of about 200 nm in thickness) formed as a lower layer by a thermal CVD method, and a plasma TEOS silicon oxide film (for example, of about 270 nm in thickness) as an upper layer. Tungsten plugs 3 are formed through such a premetal insulating film.

A first wiring layer M1 on the film 5 is comprised of an insulating barrier film 14 made of a SiCN film (for example, of about 50 nm in thickness) as a lower layer, a plasma silicon oxide film 15 which is a main interlayer insulating film (for example, of about 150 nm in thickness), and a copper wiring 13 or the like embedded in wiring trenches formed therein.

Second to sixth wiring layers M2, M3, M4, M5, and M6 on the layer M1 have substantially the same structure to each other. Each layer is comprised of a composite insulating barrier film (liner film) 24, 34, 44, 54, or 64 including a SiCO film (for example, of about 30 nm in thickness) as a lower layer/SiCN film (for example, of about 30 nm), and a main interlayer insulating film 25, 35, 45, 55, or 65 occupying most of the upper layer. Each of the main interlayer insulating films 25, 35, 45, 55, and 65 is comprised of a carbon doped silicon oxide film as a lower layer, that is, a SiOC film (for example, of about 350 nm in thickness), and a plasma TEOS silicon oxide film (for example, of about 80 nm in thickness) as a cap film. Copper embedded wirings 23, 33, 43, 53, and 63 including a copper plug and a copper wiring are formed through the interlayer insulating film.

A seventh wiring layer M7 and an eighth wiring layer M8 formed over the layer M6 have substantially the same structure to each other. Each layer is comprised of an insulating barrier film 74 or 84 formed of a SiCN film (for example, of about 70 nm in thickness) as a lower layer, and a main interlayer insulating film 75 or 85 as an upper layer. The main interlayer insulating film 75 or 85 is comprised of a plasma TEOS silicon oxide film (for example, of about 250 nm in thickness), a FSG film (for example, of about 300 nm in thickness), and a USG film serving as a cap film (for example, of about 200 nm in thickness) from the lower layer side. Copper embedded wirings 73 and 83 including a copper plug and a copper wiring are formed through the interlayer insulating films.

A ninth wiring layer M9 and a tenth wiring layer M10 formed over the layer M8 have substantially the same structure to each other. Each layer is divided into an interlayer as a lower layer and an intralayer as an upper layer. The interlayer insulating film is comprised of an insulating barrier film 94b or 104b made of a SiCN film (for example, of about 70 nm in thickness) as a lower layer, and a main interlayer insulating film as an upper layer. The main interlayer insulating film is comprised of a FSG film 95b or 105b (for example, of about 800 nm in thickness) as a lower layer, and a USG film 96b or 106b (for example, of about 100 nm in thickness) serving as a cap film positioned as an upper layer. The intralayer insulating film is comprised of an insulating barrier film 94a or 104a made of a SiCN film (for example, of about 50 nm in thickness) as a lower layer, and a main interlayer insulating film as an upper layer. The main interlayer insulating film is comprised of a FSG film 95a or 105a (for example, of about 1200 nm in thickness) as a lower layer, and a USG film 96a or 106a (for example, of about 100 nm in thickness) serving as a cap film positioned as an upper layer. Copper embedded wirings 93 and 103 including a copper plug and a copper wiring are formed through the interlayer insulating film and the intralayer insulating film.

An uppermost wiring layer (pad layer) AP formed on the layer M10 is comprised of an insulating barrier film made of a SiCN film 114 (for example, of about 10 nm in thickness) as a lower layer, a main interlayer insulating film made of an intermediate USG film 117 (for example, of about 900 nm in thickness), and a final passivation film made of an outermost plasma SiN119 (for example, of about 600 nm in thickness). Tangusten plugs 113 are provided through the interlayer insulating films, and an aluminum bonding pad 118 (for example, of about 1000 nm in thickness) is provided over the USG film 117. The aluminum bonding pad 118 and the tungsten plug 113 have a titanium bonding layer 151 (for example, of about 100 nm in thickness) as the lower layer, and a titanium nitride barrier metal layer 152 (for example, of about 30 nm in thickness) as the upper layer if necessary. A titanium nitride layer 153 (for example, of about 70 nm in thickness) is formed over the bonding pad 118, and an opening is formed in the layer 153 and the plasma SiN 119 to form a bonding pad opening 163.

Instead of the aluminum bonding pad 118, a copper-based bonding pad may be used.

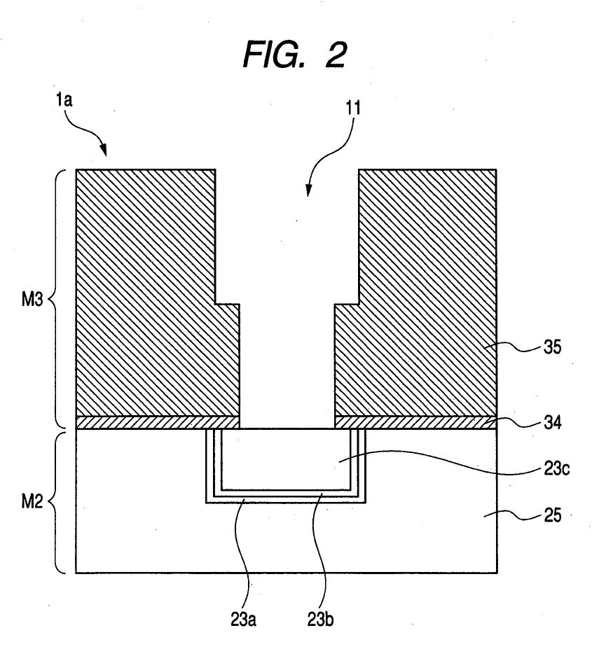

2. Explanation of Wiring Embedding Process in Manufacturing Method of Semiconductor Integrated Circuit Device According to One Embodiment of Present Application (mainly see FIGS. 2 to 6)

The following section will describe a wiring embedding process by taking the third wiring layer M3 (copper) shown in FIG. 1 of Section 1 (copper damascene wiring layer or embedded wiring layer) as an example. However, the wiring embedding process in this section can be applied to other copper damascene wiring layers or embedded wiring layers in the same way.

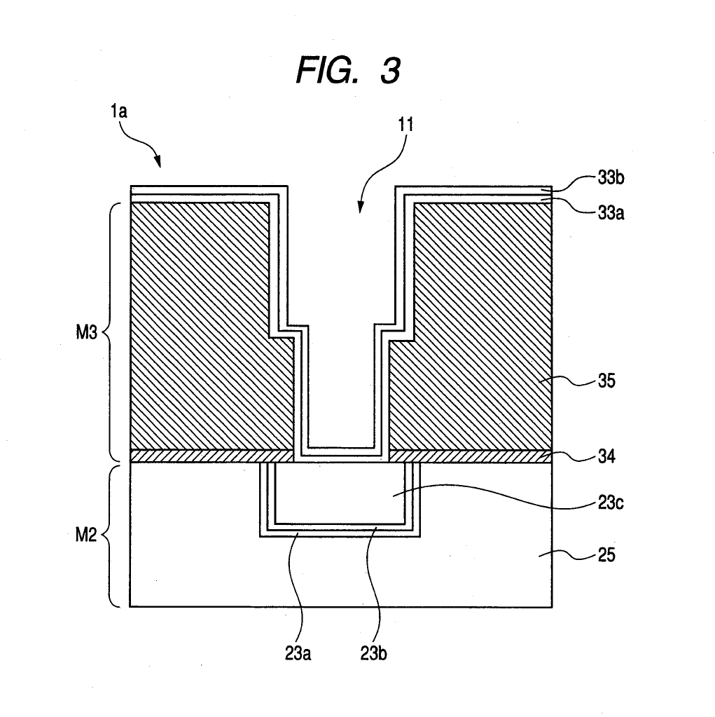

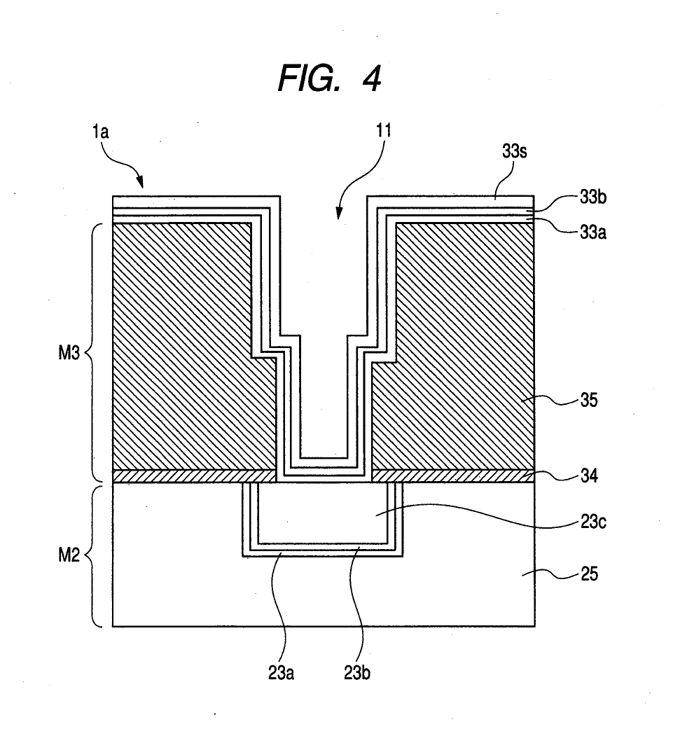

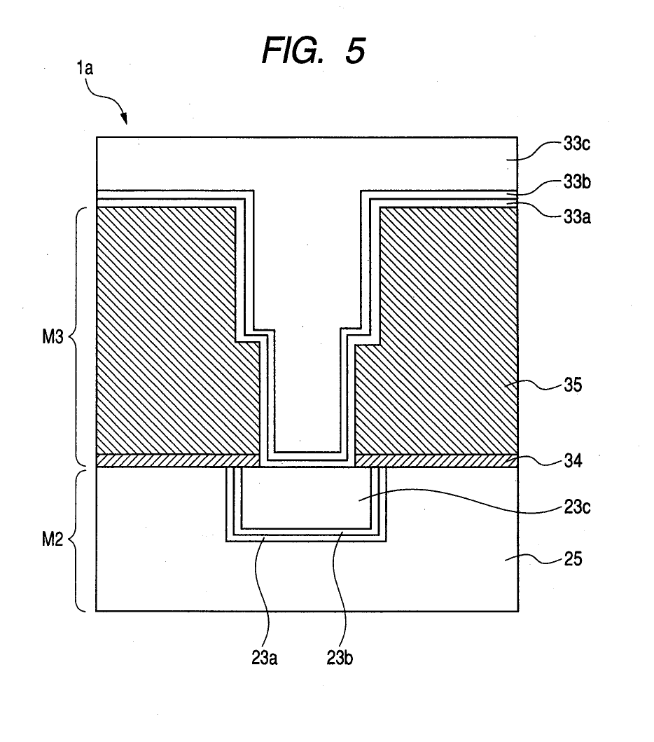

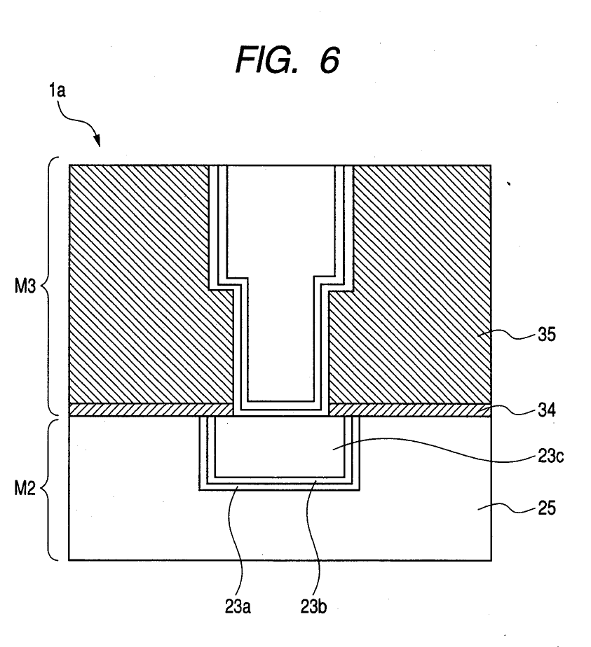

FIG. 2 is a device cross-sectional flow diagram (at the time of completion of a trench and a via) of the wiring embedding process in the manufacturing method of the semiconductor integrated circuit device according to the embodiment of the present application. FIG. 3 is a device cross-sectional flow diagram (at the time of completion of formation of a Ta film) of the wiring embedding process in the manufacturing method of the semiconductor integrated circuit device according to the embodiment of the present application. FIG. 4 is a device cross-sectional flow diagram (at the time of completion of formation of a copper seed film) of the wiring embedding process in the manufacturing method of the semiconductor integrated circuit device according to the embodiment of the present application. FIG. 5 is a device cross-sectional flow diagram (at the time of completion of copper plating) of the wiring embedding process in the manufacturing method of the semiconductor integrated circuit device according to the embodiment of the present application. FIG. 6 is a device cross-sectional flow diagram (at the time of completion of metal CMP) of the wiring embedding process in the manufacturing method of the semiconductor integrated circuit device according to the embodiment of the present application. Based on these figures, the following will describe the wiring embedding process in the manufacturing method of the semiconductor integrated circuit device according to the embodiment of the present application.

First, the insulating barrier film 34 and the main interlayer insulating film 35 are deposited by chemical vapor deposition (CVD) or the like. Then, as shown in FIG. 2, the via and trench 11 reaching a Cu film 23c as a lower layer is formed in the main interlayer insulating film 35 and the insulating barrier film 34, for example, by a via first method or the like. The second wiring layer M2 is positioned under the third wiring layer M3, and includes a TaN film 23a, a Ta film 23b, and a Cu film 23c embedded in the main interlayer insulating film 25.

Then, as shown in FIG. 3, for example, a tantalum nitride film 33a (TaN film) having a thickness of about 5 nm (first thickness) is formed over an upper surface 1a of the wafer and the substantially entire surface of an inner surface of the via and trench 11 by reactive sputter deposition using a tantalum target. Process conditions are, for example, as follows: wafer stage temperature, ordinary temperature (room temperature); DC power applied to an upper electrode, about 15 kilowatts; high frequency power applied to a lower electrode (for example, 13.56 MHz), about 600 watts; Argon flow rate, about 5 sccm; nitrogen flow rate, about 30 sccm; process pressure, about 0.16 Pa; and process time, about 5 seconds.

Subsequently, for example, a tantalum film 33b (Ta film) having a thickness of about 10 nm (second thickness) is formed over the tantalum nitride film 33a by sputtering using the tantalum target. Process conditions are, for example, as follows: wafer stage temperature, ordinary temperature (room temperature); DC power applied to the upper electrode, about 15 kilowatts; high frequency power applied to the lower electrode (for example, 13.56 MHz), about 200 watts; Argon flow rate, about 5 sccm; process pressure, about 0.06 Pa; and process time, about 15 seconds. Instead of the tantalum film 33b, a ruthenium film having substantially the same thickness may be deposited by sputtering or the like (or can be performed by a CVD or the like). The ruthenium film is superior in crystallizing consistency and adhesion to copper. The first barrier metal film is not limited to the tantalum nitride film as long as it can contain as a principal component a first metal nitride having a barrier property against diffusion of copper (which is desirably a film having better consistency with the interlayer insulating film). The second barrier metal film is not limited to the tantalum film or ruthenium film, and may be one containing as a principal component the first metal or other metal element having a barrier property against diffusion of copper (which is desirably a film having better consistency with copper).

Then, as shown in FIG. 4, a copper seed film 33s (Cu film) is formed by sputtering deposition using a copper target.

Then, as shown in FIG. 5, a copper film 33c (Cu film) is formed by electroplating so as to cover the upper surface 1a of the wafer and to fill the via and trench 11 therewith.

Then, as shown in FIG. 6, unnecessary parts of the copper film 33c, tantalum film 33b, and tantalum nitride film 33a are planarized by chemical and mechanical polishing or the like, so that the unnecessary parts of the films are removed. In this way, the third wiring layer M3 is finished. Further, the above steps are repeatedly substantially in the same way to thereby form a multi-layer wiring structure shown in FIG. 1.

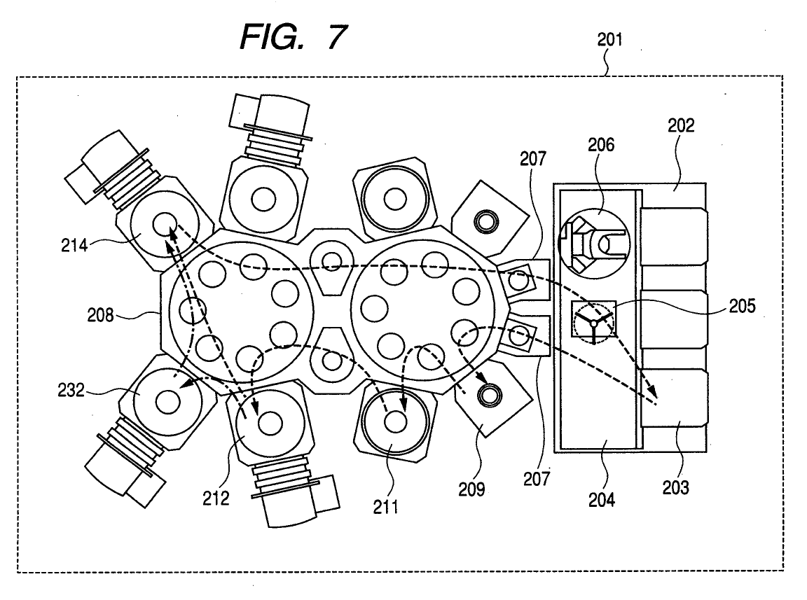

3. Explanation of Manufacturing Device or the like Used in Wiring Embedding Process in Manufacturing Method of Semiconductor Integrated Circuit Device According to One Embodiment of Present Application (mainly see FIGS. 7 to 9)

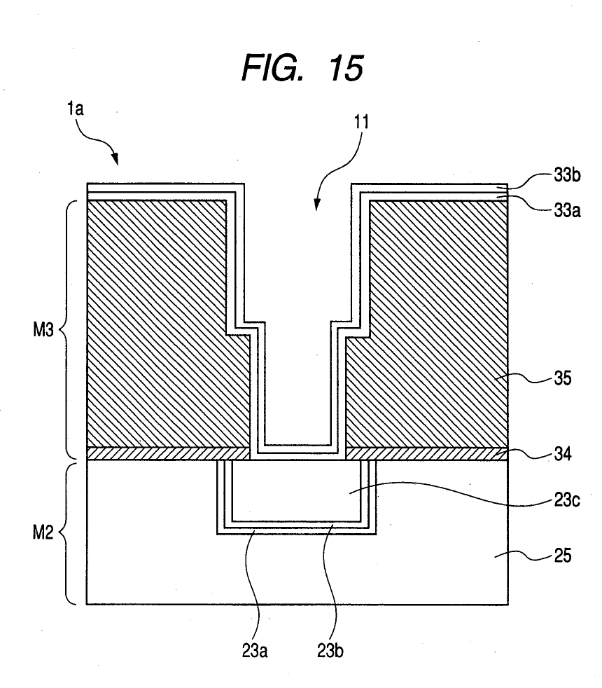

As the process route, in a Ta/TaN barrier metal process of Section 2 (FIG. 3) and Section 5 (FIGS. 15 to 17), a route represented by a broken line is used, and in a Ru/TaN barrier metal process, a route represented by an alternate long and short dash line is used. In the following description, Section 2 corresponds to FIGS. 3 and 4, and Section 5 corresponds to FIGS. 15 to 18.

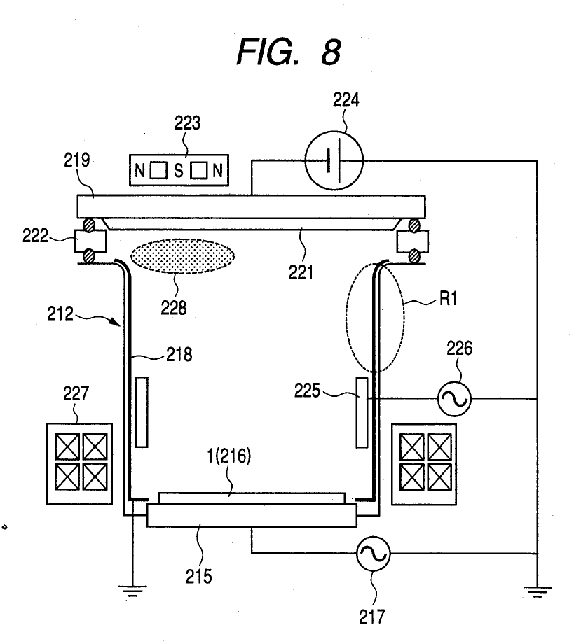

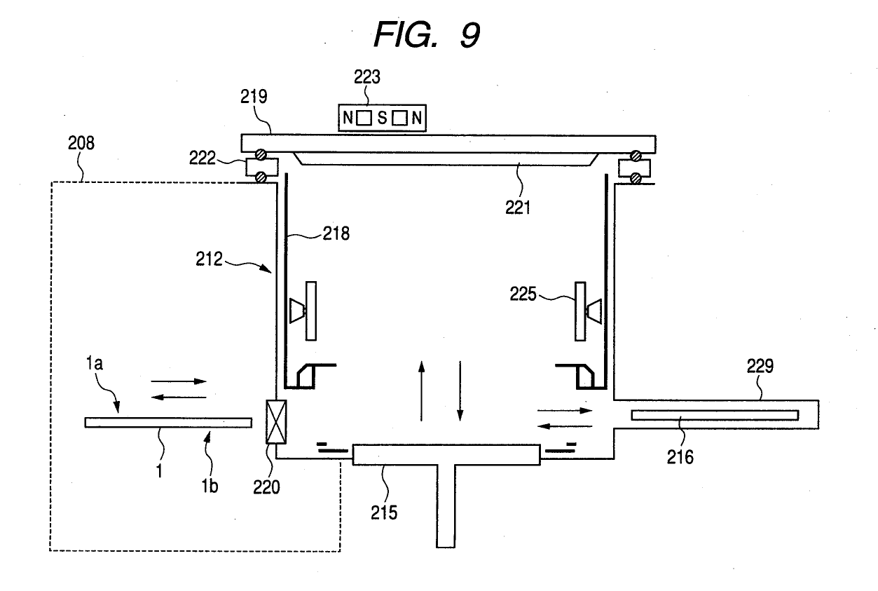

FIG. 7 is an exemplary diagram of an upper surface of a multi-chamber type manufacturing device used for the wiring embedding process in the manufacturing method of the semiconductor integrated circuit device according to the embodiment of the present application. FIG. 8 is an exemplary cross-sectional view of a sputtering chamber for tantalum or tantalum nitride in the multi-chamber type manufacturing device shown in FIG. 7 (at the time of deposition on the wafer or the like). FIG. 9 is an exemplary cross-sectional view of a sputtering chamber for tantalum or tantalum nitride in the multi-chamber type manufacturing device shown in FIG. 7 (at the time of introduction or discharge into or from the wafer or the like). Based on these figures, the following will describe the outline of an operation or the like of the manufacturing device used for the wiring embedding process in the manufacturing method of the semiconductor integrated circuit device according to the embodiment of the present application.

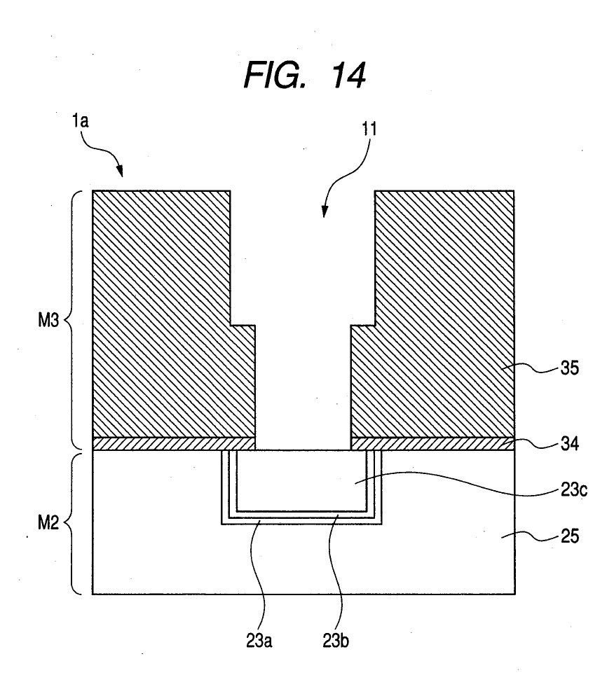

First, as shown in FIG. 2 (FIG. 14 in Section 5), the wafer 1 to be processed with the via and trench 11 formed therein is accommodated in a hoop 203 (airtight wafer transfer container), and is set in a load port 202 of a multi-chamber wafer processor 201.

The wafer 1 to be processed is carried into a vacuum delivery chamber 208 through a pre-cleaning chamber 204 with a down-flow mechanism 205 and a load lock chamber 207 by a delivery robot 206. The wafer 1 to be processed is carried from the vacuum delivery chamber 208 into the degas chamber 209, and subjected to a vacuum baking process (degas process). Subsequently, the wafer 1 to be processed is moved to a pretreatment chamber 211 via the vacuum delivery chamber 208, and then subjected to the pretreatment. The term “pretreatment” as used herein means removal process of impurities, such as CuO, remaining on the exposed surface of the Cu film 23c as a lower layer, by physical sputter etching using Ar ions, or by a reduction reaction with H2 radicals. Then, the wafer 1 to be processed is transferred to a Ta and TaN deposition chamber 212 via the vacuum delivery chamber 208, where sputtering deposition of a barrier metal film (including sputter etching and re-sputter deposition of the tantalum film in the case of Section 5) is performed. Then, the wafer 1 to be processed is transferred to a copper seed deposition chamber 214 via the vacuum delivery chamber 208, so that a copper seed film 33s is deposited by sputtering. In the Ru/TaN barrier metal process, the wafer 1 to be processed is previously transferred to a ruthenum deposition chamber 232 via the vacuum delivery chamber 208, so that a ruthenium barrier film is deposited by sputtering or the like.

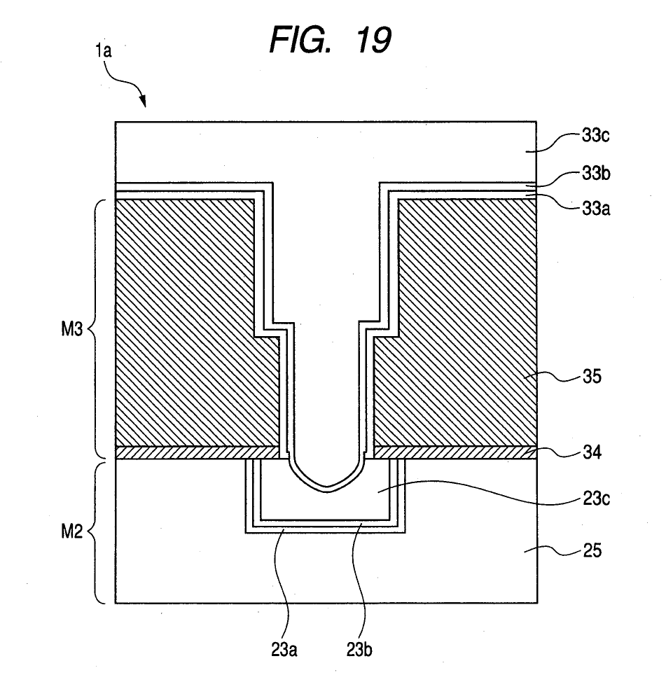

After forming the copper seed film 33s, the wafer 1 to be processed is returned to the hoop 203 via the vacuum delivery chamber 208, the load lock chamber 207, and the pre-cleaning chamber 204. Thereafter, the wafer 1 is transferred to a plating device, so that the electroplating of copper is performed as shown in FIG. 5 (FIG. 19).

Then, the structure of the Ta and TaN deposition chamber 212 (or TaN deposition chamber) shown in FIG. 7 will be described below. First, the time of deposition over the wafer (or formation of a coating on the inner wall) will be described below. As shown in FIG. 8, the wafer 1 to be processed or shutter disk 216 (wafer-like metal plate) is set over a wafer stage 215 (lower electrode). The shutter disk 216 is comprised of, for example, a disk-shaped member having the same shape as a stainless wafer, and is set on the waver stage 215 when performing the deposition process without disposing the wafer 1 so as to prevent deposition on the wafer stage 215. A shield 218 (whose main part is a substantially cylindrical member made of aluminum and stainless, and normally grounded) is provided inside the outer wall 212 of the Ta and TaN deposition chamber so as to prevent deposition of a sputtered film on the chamber outer wall 212. An upper electrode 219 is provided at the upper end of the chamber outer wall 212 via a vacuum seal 222. A tantalum target 221 is attached to the lower surface of the outer wall 212. The upper electrode 219 is coupled to a DC power supply 224 for biasing the upper electrode, and is used to excite an argon plasma 228 or the like together with an upper magnet 223. In contrast, the lower electrode 215 is coupled to a high-frequency power supply 217 for biasing the lower electrode (13.56 MHz), and works with a lower magnet 227 to cause sputter particles to be uniformly drawn into the surface of the wafer. An excitation coil 225 for sputter etching (coil-like electrode) located in the intermediate position is coupled to the high-frequency and DC power supply 226 for sputter etching, whereby a high-frequency power is mainly used for excitation of argon plasma near the wafer in the sputter etching, and the DC power is mainly used for auxiliary sputter deposition.

Next, the following will describe introduction and discharge of the wafer 1 or shutter disk 216 into and from the chamber 212. As shown in FIG. 9, at the time of introduction and discharge of the wafer 1 or the like, the wafer stage 215 descends together with a part of the shield to a lower level than that at the time of deposition over the wafer 1 or the like. In this state, the wafer 1 is transferred to between the wafer stage 215 and the vacuum delivery chamber 208 (via a wafer introduction and discharge gate 220), and the shatter disk 216 is transferred to between the wafer stage 215 and the shutter disk shelf 229.

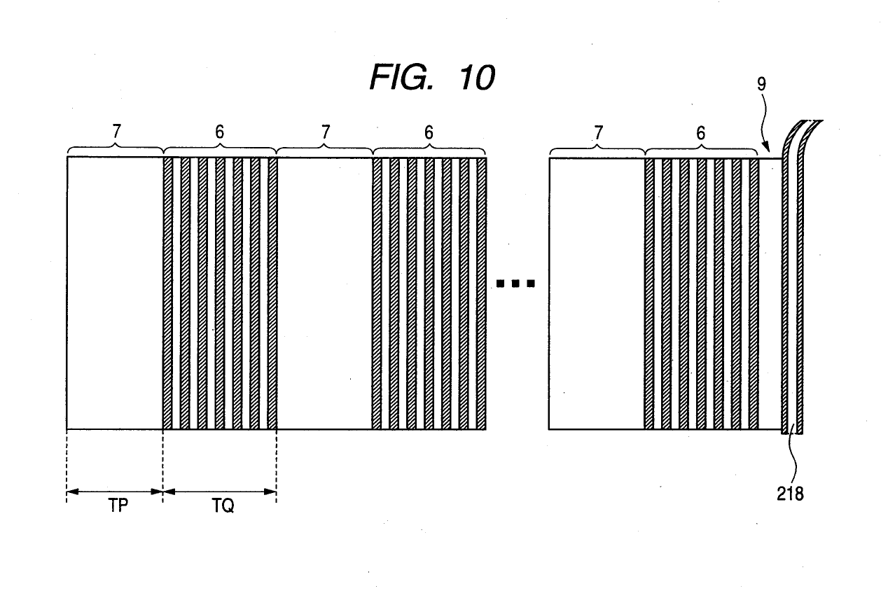

4. Explanation of Procedure in Applying Wiring Embedding Process to Mass production in Manufacturing Method of Semiconductor Integrated Circuit Device According to One Embodiment of Present Application (mainly see FIGS. 10 to 13)

This section will describe in detail a barrier metal film deposition process described in Section 2 with reference to FIG. 3.

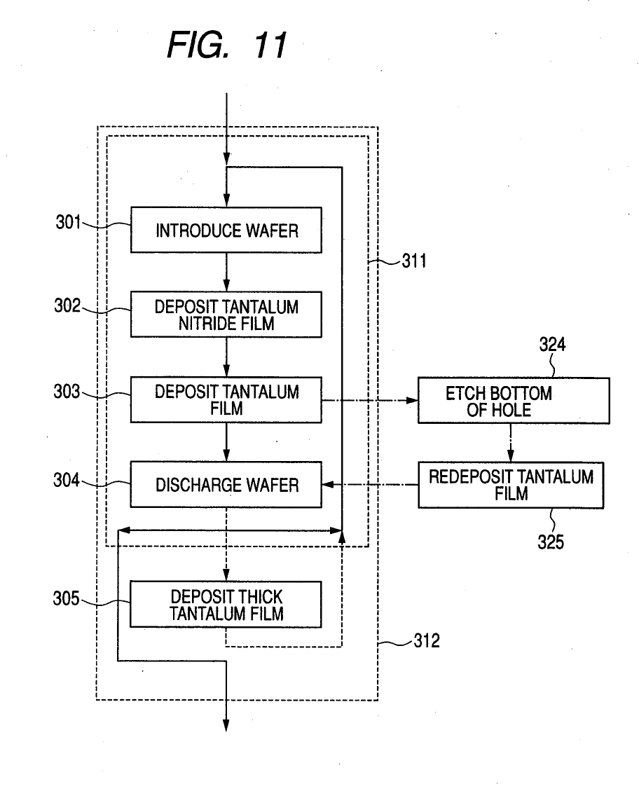

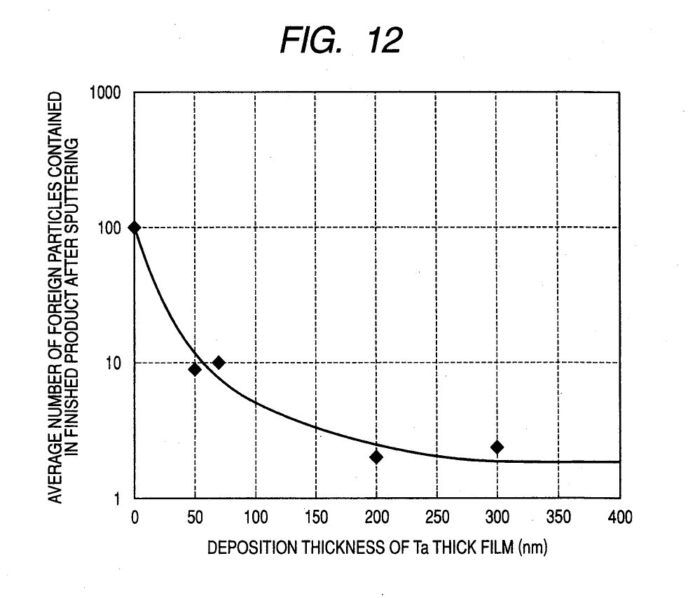

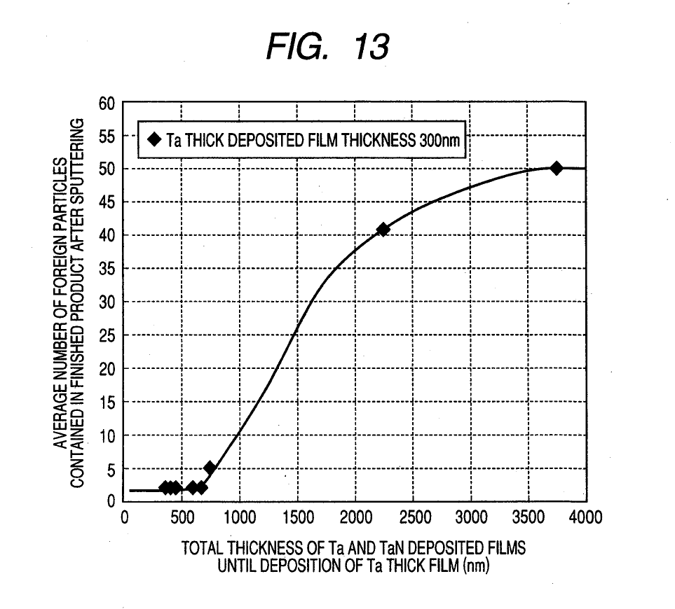

FIG. 10 is a partial enlarged cross-sectional view of a shield enlargement region R1 of FIG. 8. FIG. 11 is a process block flow diagram for explaining a procedure in applying the wiring embedding process to mass production in the manufacturing method of the semiconductor integrated circuit device according to the embodiment of the present application. FIG. 12 is a data plot diagram of the plot of the average number of foreign particles (per wafer) contained in a finished product after completion of deposition of tantalum and tantalum nitride by sputtering with respect to the thickness of a tantalum film which is a thick metal film (inner wall coating film). FIG. 13 is a data plot diagram of the plot of the average number of foreign particles (per wafer) contained in a finished product after completion of deposition of tantalum and tantalum nitride films by sputtering with respect to the total thickness of the deposited film directly before a deposition process of the thick metal film (inner wall coating film) (at the time between the inner wall coating film deposition process and a previous inner wall coating film deposition process). Now, based on these figures, the following will describe the procedure in applying the wiring embedding process to mass production in manufacturing method of the semiconductor integrated circuit device according to one embodiment of present application.

The process (corresponding to FIG. 3 of Section 2) including a barrier metal deposition in the mass production that can reduce the occurrence of foreign material is performed as shown in FIG. 11. That is, as shown in FIGS. 8 and 9, the wafer 1 to be processed (wafer obtained after the via and trench formation step shown in FIG. 2 is completed) is introduced and set over the wafer stage 215 within the Ta and TaN deposition chamber 212 through the wafer introduction and discharge gate 220 with its device surface 1a directed upward (wafer introduction step S301 in FIG. 11).

Then, a tantalum nitride film deposition step S302 (see FIG. 11) is performed in this state (that is, which means the process on the same stage in the same chamber as in a previous step, note that the same goes for the description below). Subsequently, a tantalum film deposition step S303 (see FIG. 11) is further performed in the same state. Then, as shown in FIG. 9, the wafer 1 to be processed is discharged to the outside of the Ta and TaN deposition chamber 212 (in the wafer discharge step 5304 shown in FIG. 11). Thereafter, the wafer 1 is transferred to form a copper sheed film (see FIG. 4).

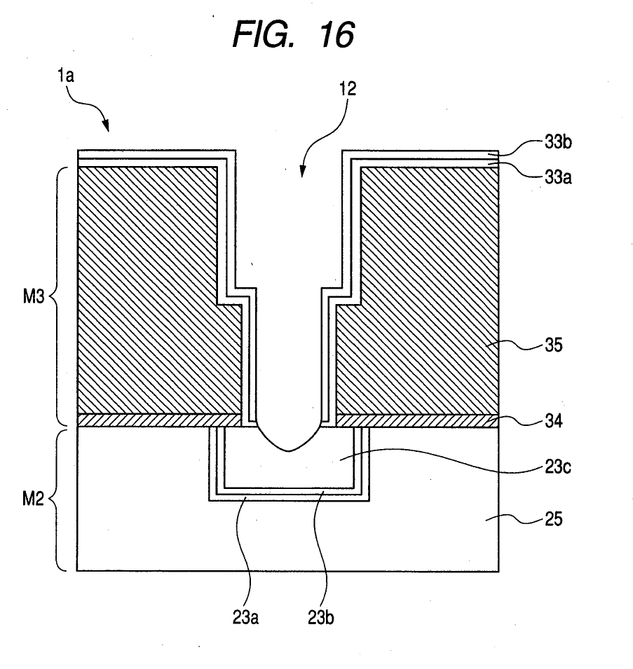

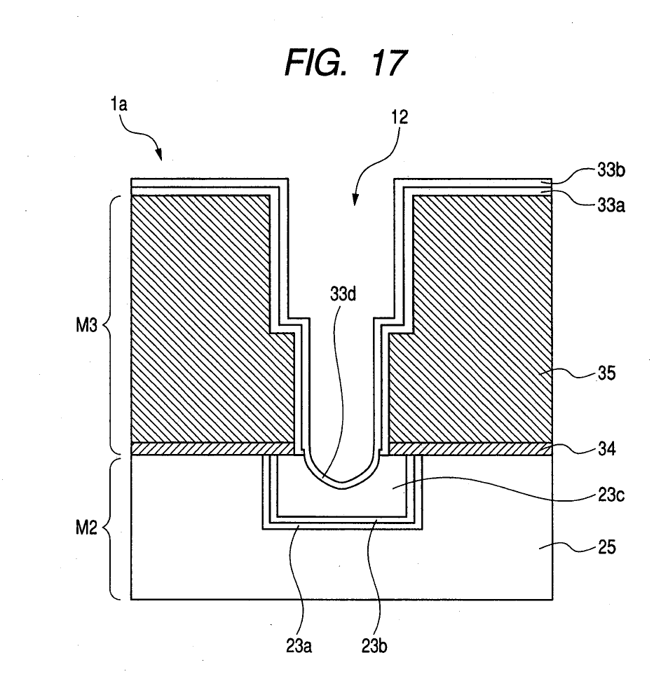

In the process described in Section 5, a hole bottom etching step S324 (see FIG. 16) and a tantalum film redeposition step S325 (see FIG. 17) are inserted between the tantalum nitride film deposition step S303 and the wafer discharge step S304 as represented by an alternate long and short dash line shown in FIG. 11.

The processes from the wafer introduction step S301 to the wafer discharge step S304 form the lower-level process recycle 311 including the barrier metal deposition process and the like. In the mass production, the lower-level process recycle 311 is repeated. As shown in FIG. 11, a thick tantalum film deposition step S305 is performed over the shield 218 (see FIGS. 8 to 10) at a predetermined timing. The thick tantalum film deposition step S305 and the lower-level process recycle 311 form an upper-level process recycle 312.

The above points will be described below using FIG. 10. FIG. 10 is an exemplary enlarged cross-sectional view of the shield enlargement region R1 of FIG. 8 obtained by repeating the upper-level process recycle 312. An initial deposited film 9 (initial Ta film) before application of the mass production is deposited over the inner surface of the shield 218, for example, in a thickness of about 10000 nm. This is provided for removing an oxide layer at a target surface, and stabilizing electrical discharge. Then, as viewed in the direction toward the left, an in-process deposited film 6 (or a deposited film at the time of the wafer process) exists in repeated deposition (of a tantalum nitride film and a tantalum film) over the wafer 1. As further viewed in the direction toward the left, a thick metal film 7 (or the inner wall covering film, a tantalum film for preventing foreign material) is deposited in a thick tantalum film deposition step S305. Then, as moving in the left direction, the in-process deposited film 6 and the thick metal film 7 are alternatively repeated.

The thickness of the thick metal film 7, that is, the thick metal film thickness TP is, for example, about 300 nm. On the other hand, the thickness of the in-process deposited film 6 directly before deposition of the thick metal film 7, that is, the total thickness TQ of the deposited film in the wafer process is, for example, about 750 nm.

That is, the predetermined timing is, for example, the time when the total thickness TQ of the deposited film in the wafer process is about 300 nm. The deposition step S305 of the thick tantalum film over the inner surface of the shield 218 is performed, for example, in the following way. The shutter disk 216 (wafer-like metal plate) with the wafer 1 not positioned on the stage 215 as illustrated in FIG. 9 is moved from the shutter disk shelf 229 to the stage 215 as shown in FIG. 8. This can prevent the undesired deposition of metal on the stage 215. In this state, the thick tantalum film deposition step S305 is performed. Process conditions are, for example, as follows: wafer stage temperature, ordinary temperature (room temperature); DC power applied to the upper electrode, about 40 kilowatts; high frequency power applied to the lower electrode (for example, 13.56 MHz), OFF state; Argon flow rate, about 15 sccm; process pressure, about 0.12 Pa; and process time, about 140 seconds.

Now, referring to FIGS. 12 and 13, the following will describe preferable ranges of the thick metal film thickness TP and of the total thickness TQ of the deposited film in the wafer process directly before deposition of the thick metal film 7. As shown in FIG. 12 (total thickness TQ of the deposited film in the last wafer process=750 nm), a preferable range of the thick metal film thickness TP is about 100 nm or larger, and preferably 150 nm or larger from the relationship between the thick metal film thickness TP (on the horizontal axis) and the average number of foreign particles per wafer at the time of completion of deposition of the tantalum nitride film and the tantalum film (on the longitudinal axis). The upper limit of the film thickness TP is generally less than 500 nm, preferably less than about 350 nm from the viewpoint of the operating rate of the device. In this way, the attachment of the tantalum film (inner wall coating film, tantalum film for preventing foreign material) which is much thicker than the tantalum film deposited over the wafer decreases the number of foreign particles. Since the tantalum film has a Young's modulus lower than that of the tantalum nitride film, the internal stress in the tantalum nitride film comprised of a plurality of layers laminated via thin tantalum films is dispersed into the thick tantalum film (inner wall coating film, tantalum film for preventing foreign material).

On the other hand, the total thickness TQ of the deposited film in the wafer process directly before the execution of the thick tantalum film deposition step S305 over the seed can be defined based on FIG. 13. That is, as plotted in FIG. 13, the average number of foreign particles per wafer at the time of completion of deposition of the tantalum nitride film and the tantalum film (on the longitudinal axis) starts to gradually increase from about a total thickness TQ of the deposited film in the wafer process (on the horizontal axis) in a range of about 600 nm to about 750 nm, and drastically increases on the right side with respect to 1000 nm. The thick tantalum film deposition step S305 is preferably performed before the total thickness TQ of the deposited film in the wafer process directly before the step S305 exceeds 1000 nm, and desirably 800 nm. The lower limit of the film thickness TP is generally 300 nm or larger, preferably 500 nm or larger from the viewpoint of the operating rate of the device. That is, the thick tantalum film deposition step S305 is preferably performed after the total thickness TQ of the deposited film in the wafer process directly before the step S305 exceeds 300 nm, and desirably 500 nm.

Normally, the sum of the thicknesses of the tantalum nitride film and the tantalum film deposited over the wafer 1 at one time is not less than 5 nm and less than 30 nm (the sum of the thicknesses of the tantalum nitride film and the ruthenium film is not less than 5 nm and less than 20 nm). The thickness of 750 nm corresponds to about 25 to 150 pieces of wafers to be processed (that is, one to six lots when 25 pieces are brought into one lot).

5. Explanation of Wiring Embedding Process in Manufacturing Method of Semiconductor Integrated Circuit Device According to Another Embodiment of Present Application (mainly see FIGS. 14 to 20)

The wiring embedding process to be described in this section is basically the same as that described in Section 2, but is different in that the respective steps shown in FIG. 16 (via bottom sputter etching step) and FIG. 17 (via bottom additional Ta film deposition step) are inserted into between the step shown in FIG. 3 (Ta film deposition step) and the step shown in FIG. 4 (copper seed film deposition step) as described in Section 2. Such a hole bottom etching process is very effective in preventing failures due to stress migration (SM) or electro migration (EM) because of a large contact area between the barrier metal at the bottom and a lower layer wiring. Normally, these processes are often applied to finer devices than in the process described in Section 2. Thus, it is very important to reduce the foreign material.

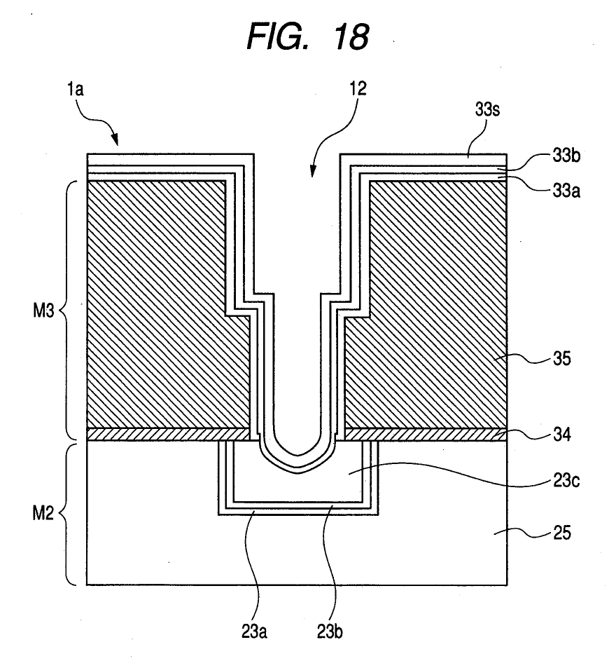

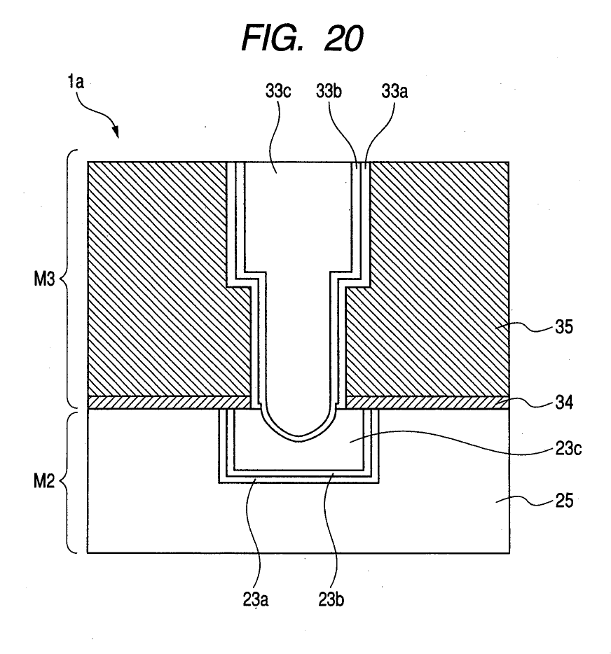

FIG. 14 is a device cross-sectional flow diagram (at the time of completion of formation of a trench and a via) of a wiring embedding process in the manufacturing method of the semiconductor integrated circuit device according to another embodiment of the present application. FIG. 15 is a device cross-sectional flow diagram (at the time of completion of formation of a Ta film) of the wiring embedding process in the manufacturing method of the semiconductor integrated circuit device according to another embodiment of the present application. FIG. 16 is a device cross-sectional flow diagram (at the time of completion of etching the bottom of a hole) of the wiring embedding process in the manufacturing method of the semiconductor integrated circuit device according to another embodiment of the present application. FIG. 17 is a device cross-sectional flow diagram (at the time of completion of formation of an additional Ta film) of the wiring embedding process in the manufacturing method of the semiconductor integrated circuit device according to another embodiment of the present application. FIG. 18 is a device cross-sectional flow diagram (at the time of completion of formation of a copper shield film) of the wiring embedding process in the manufacturing method of the semiconductor integrated circuit device according to another embodiment of the present application. FIG. 19 is a device cross-sectional flow diagram (at the time of completion of copper plating) of the wiring embedding process in the manufacturing method of the semiconductor integrated circuit device according to another embodiment of the present application. FIG. 20 is a device cross-sectional flow diagram (at the time of completion of metal CMP) of the wiring embedding process in the manufacturing method of the semiconductor integrated circuit device according to another embodiment of the present application. Based on these figures, the following will describe the wiring embedding process in the manufacturing method of the semiconductor integrated circuit device according to another embodiment of the present application.

First, the insulating barrier film 34 and the main interlayer insulating film 35 are deposited by the CVD or the like in the same way as that described in Section 2. Then, as shown in FIG. 14, the via and trench 11 reaching the Cu film 23c as a lower layer is formed in the main interlayer insulating film 35 and the insulating barrier film 34, for example, by a via-first method or the like. The second wiring layer M2 is positioned below the third wiring layer M3, and includes the TaN film 23a, the Ta film 23b, and the Cu film 23c embedded in the main interlayer insulating film 25.

Then, as shown in FIG. 15, for example, the tantalum nitride film 33a (TaN film) having a thickness of about 5 nm is formed over the upper surface 1a of the wafer and the substantially entire inner surface of the via and trench 11 by reactive sputtering deposition using a tantalum target. Process conditions are, for example, as follows: wafer stage temperature, ordinary temperature (room temperature); DC power applied to the upper electrode, about 20 kilowatts; high frequency power applied to the lower electrode (for example, 13.56 MHz), about 600 watts; Argon flow rate, about 5 sccm; nitrogen flow rate, about 30 sccm; process pressure, about 0.16 Pa; and process time, about 5 seconds.

Subsequently, for example, the tantalum film 33b (Ta film) having a thickness of about 10 nm is formed over the tantalum nitride film 33a by sputtering using the tantalum target. Process conditions are, for example, as follows: wafer stage temperature, ordinary temperature (room temperature); DC power applied to an upper electrode, about 20 kilowatts; high frequency power applied to a lower electrode (for example, 13.56 MHz), about 200 watts; Argon flow rate, about 5 sccm; process pressure, about 0.06 Pa; and process time, about 15 seconds.

Then, as shown in FIG. 16, the tantalum film 33b and the tantalum nitride film 33a at the bottom of the via, and the Cu film 23c as a lower layer are etched by sputtering. Process conditions are, for example, as follows: wafer stage temperature, ordinary temperature (room temperature); DC power applied to the upper electrode, about 500 watts; high frequency power applied to the lower electrode (for example, 13.56 MHz), about 500 watts; DC power applied to a coil, about 500 watts; high frequency power applied to the coil (for example, 2 MHz), about 1000 watts; Argon flow rate, about 10 sccm; process pressure, about 0.15 Pa; and process time, about 20 seconds.

Then, as shown in FIG. 17, a via bottom Ta film 33d (for example, of about 5 nm in thickness) is deposited again on a part etched by the sputter etching. Process conditions are, for example, as follows: wafer stage temperature, ordinary temperature (room temperature); DC power applied to the upper electrode, about 20 kilowatts; high frequency power applied to the lower electrode (for example, 13.56 MHz), about 200 watts; Argon flow rate, about 5 sccm; process pressure, about 0.06 Pa; and process time, about 5 seconds.

Then, as shown in FIG. 18, the copper seed film 33s (Cu film) is deposited by sputtering using a copper target.

Then, as shown in FIG. 19, the copper film 33c (Cu film) is formed by electroplating so as to cover the upper surface 1a of the wafer and to fill the via and trench 11.

Then, as shown in FIG. 20, the copper film 33c, tantalum film 33b, and tantalum nitride film 33a have the surfaces thereof planarized by chemical and mechanical polishing or the like, so that the unnecessary parts of the films are removed. In this way, the third wiring layer M3 is finished. Further, the above steps are repeatedly substantially in the same way to thereby form a multi-layer wiring structure shown in FIG. 1.

6. Summary

Although the invention made by the inventors has been specifically described based on the preferred embodiments, the invention is not limited thereto. It will be apparent to those skilled in the art that various modifications can be made to the presently disclosed embodiments without departing from the scope of the invention.

For example, although this embodiment has specifically described the example of the copper-based damascene wiring (single damascene and dual damascene wirings), the invention is not limited thereto. It is apparent that the invention can also be applied to other damascene wirings other than the copper-based one, such as a silver-based damascene wiring.

Although the above-mentioned embodiments have specifically described the examples of deposition of the barrier metal film of the damascene wiring (embedded wiring), the invention is not limited thereto. It is apparent that the invention can also be widely applied to prevent generation of foreign material in the sputtering deposition.

Further, although the thick tantalum film has been specifically described as one example of use of the inner wall coating film for preventing foreign material, the invention is not limited thereto. It is needless to say that the invention can use any other film that has the stress in the same direction as that of the in-process deposited film inevitably deposited during the deposition process over the wafer, which has a relatively small Young's modulus, and which can be deposited by sputtering using the same target as that in the deposition process over the wafer.

What is claimed is:

1. A manufacturing method of a semiconductor integrated circuit device, comprising the steps of:
(a) introducing a wafer to be processed into a chamber;
(b) depositing a tantalum nitride film having a first thickness over the wafer to be processed in the chamber by sputtering;
(c) after the step (b), depositing a first tantalum film having a second thickness over the wafer to be processed in the chamber by sputtering;
(d) discharging the wafer to be processed to an outside of the chamber;
(e) sequentially applying a lower-level process cycle including the steps (a) to (d) to a plurality of wafers to be processed that are different from the wafer belonging to a previous lower-level process cycle;
(f) after the step (e), depositing a second tantalum film over an inner wall of the chamber by sputtering in the chamber, said second tantalum film having a third thickness much larger than the second thickness; and
(g) repeating a higher-level process cycle including the steps (a) to (f).

2. The manufacturing method of a semiconductor integrated circuit device according to claim 1, wherein the step (f) is performed before a total thickness of a deposited film in a last wafer process exceeds 1000 nm.

3. The manufacturing method of a semiconductor integrated circuit device according to claim 2, wherein the step (f) is performed after the total thickness of the deposited film in the last wafer process exceeds 300 nm.

4. The manufacturing method of a semiconductor integrated circuit device according to claim 3, wherein the third thickness is not less than 100 nm, and less than 500 nm.

5. The manufacturing method of a semiconductor integrated circuit device according to claim 4, wherein a sum of the first thickness and the second thickness is not less than 5 nm, and less than 30 nm.

6. The manufacturing method of a semiconductor integrated circuit device according to claim 5, wherein the step (f) is performed after the total thickness of the deposited film in the last wafer process exceeds 500 nm.

7. The manufacturing method of the semiconductor integrated circuit device according to claim 6, wherein the third thickness is not less than 150 nm, and less than 350 nm.

8. The manufacturing method of a semiconductor integrated circuit device according to claim 7, wherein the step (f) is performed before the total thickness of the deposited film in the last wafer process exceeds 800 nm.

9. A manufacturing method of a semiconductor integrated circuit device, comprising the steps of:
(a) introducing a wafer to be processed into a first chamber;
(b) depositing a tantalum nitride film having a first thickness over the wafer to be processed in the first chamber;
(c) after the step (b), taking the wafer to be processed out of the first chamber to introduce the wafer into a second chamber;
(d) depositing a ruthenium film having a second thickness over the wafer to be processed by sputtering in the second chamber;
(e) discharging the wafer to be processed to an outside of the second chamber;
(f) sequentially applying a lower-level process cycle including the steps (a) to (e) to a plurality of wafers to be processed that are different from the wafer belonging to a previous lower-level process cycle;
(g) after the step (f), depositing a tantalum film over an inner wall of the first chamber by sputtering in the first chamber, said tantalum film having a third thickness much larger than the first thickness; and
(h) repeating a higher-level process cycle including the steps (a) to (g).

10. The manufacturing method of a semiconductor integrated circuit device according to claim 9, wherein the step (g) is performed before the total thickness of a deposited film in a last wafer process exceeds 1000 nm.

11. The manufacturing method of a semiconductor integrated circuit device according to claim 10, wherein the step (g) is performed after the total thickness of the deposited film in the last wafer process exceeds 300 nm.

12. The manufacturing method of a semiconductor integrated circuit device according to claim 11, wherein the third thickness is not less than 100 nm, and less than 500 nm.

13. The manufacturing method of a semiconductor integrated circuit device according to claim 12, wherein the second thickness is not less than 5 nm, and less than 20 nm.

14. The manufacturing method of the semiconductor integrated circuit device according to claim 13, wherein the step (g) is performed after the total thickness of the deposited film in the last wafer process exceeds 500 nm.

15. The manufacturing method of a semiconductor integrated circuit device according to claim 14, wherein the third thickness is not less than 150 nm, and less than 350 nm.

16. The manufacturing method of a semiconductor integrated circuit device according to claim 15, wherein the step (g) is performed before the total thickness of the deposited film in the last wafer process exceeds 800 nm.

17. A manufacturing method of a semiconductor integrated circuit device, comprising the steps of:
(a) introducing a wafer to be processed into a chamber;
(b) depositing a first barrier metal film having a first thickness over the wafer to be processed in the chamber by sputtering, said first barrier metal film containing a nitride of a first metal as a principal component;
(c) after the step (b), depositing a second barrier metal film having a second thickness over the wafer to be processed by sputtering in the chamber, said second barrier metal film containing the first metal as a principal component;
(d) discharging the wafer to be processed to an outside of the chamber;
(e) sequentially applying a lower-level process cycle including the steps (a) to (d) to a plurality of wafers to be processed that are different from the wafer belonging to a previous lower-level process cycle;
(f) after the step (e), depositing an inner wall coating film over an inner wall of the chamber by sputtering in the chamber, said inner wall coating film having a third thickness much larger than the second thickness, and containing the first metal as a principal component; and
(g) repeating a higher-level process cycle including the steps (a) to (f),
wherein each of the first barrier metal film and the inner wall coating film has a compression stress.

18. The manufacturing method of a semiconductor integrated circuit device according to claim 17, wherein the step (f) is performed before a total thickness of a deposited film in a last wafer process exceeds 1000 nm.

19. The manufacturing method of a semiconductor integrated circuit device according to claim 18, the step (f) is performed after the total thickness of the deposited film in the last wafer process exceeds 300 nm.

20. The manufacturing method of a semiconductor integrated circuit device according to claim 19, the third thickness is not less than 100 nm, and less than 500 nm.

21. The manufacturing method of a semiconductor integrated circuit device according to claim 17, wherein the second barrier metal film has a compression stress like the first barrier metal film and the inner wall coating film.

22. A manufacturing method of a semiconductor integrated circuit device, comprising the steps of:
(a) introducing a wafer to be processed into a chamber;
(b) depositing a first barrier metal film having a first thickness over the wafer to be processed in the chamber by sputtering;
(c) after the step (b), depositing a second barrier metal film having a second thickness over the wafer to be processed by sputtering in the chamber;
(d) discharging the wafer to be processed to an outside of the chamber;
(e) sequentially applying a lower-level process cycle including the steps (a) to (d) to a plurality of wafers to be processed that are different from the wafer belonging to a previous lower-level process cycle;
(f) after the step (e), depositing an inner wall coating film over an inner wall of the chamber by sputtering in the chamber, said inner wall coating film having a third thickness larger than the total thickness of the first film and the second film; and
(g) repeating a higher-level process cycle including the steps (a) to (f),
wherein each of the first barrier metal film and the second barrier metal film has a compression stress; and
wherein the inner wall coating film is the same as one of the first barrier metal film and the second barrier metal film.

23. The manufacturing method of a semiconductor integrated circuit device according to claim 22, wherein the inner wall coating film is the same as one having a lower Young's modulus of the first barrier metal film and the second barrier metal film.
